(19) United States
(12) Patent Application Publication
(10) Pub. No.: US 2005/0007205 A1
(43) Pub. Date: Jan. 13, 2005

(54) Low power crystal oscillator

(76) Inventor: Simon Bridger, Auckland (NZ)

Correspondence Address: WOODCOCK WASHBURN LLP, ONE LIBERTY PLACE, 46TH FLOOR, 1650 MARKET STREET, PHILADELPHIA, PA, 19103, US

(21) Appl. No.: 10/872,872

(22) Filed: Jun. 21, 2004

(30) Foreign Application Priority Data
Jun. 19, 2003 (NZ) 526595

(51) Int. Cl. H03B 5/12

(52) U.S. Cl. 331/108 C

(57) ABSTRACT

The present invention relates to a timing system including an integrated circuit having an oscillator that provides both high and low frequency clock signals from a single high frequency crystal without the necessity of a tuning fork crystal. The low frequency signal is available for time-keeping applications, with low power consumption during “idle” periods. The high performance high frequency signal is available on demand for clock and frequency reference use. The oscillator of the present invention provides improved time-keeping accuracy, whilst size, cost and component count is reduced. Furthermore, phase noise and other critical parameters of the high frequency oscillator are not compromised. Shock vulnerability, a known problem for tuning fork crystals, is reduced.

### CROSS REFERENCE TO RELATED APPLICATIONS

This application claims priority under 37 USC § 119 (a-d) to New Zealand Provisional Application No. 526595 filed Jun. 19, 2003 which is herein incorporated by reference.

### FIELD OF THE INVENTION

The present invention relates to crystal oscillator systems particularly, but not solely for the provision of low frequency real time clock signals at low standby power in applications which also require a high accuracy clock signal in full operating mode.

### BACKGROUND OF THE INVENTION

Electronic apparatus frequently requires both a high frequency clock signal, and a low-power, low frequency clock signal. Examples of such equipment are Global Positioning System (GPS) and Code Division Multiple Access (CDMA) radios, and many other applications that use microprocessors. The high frequency signal must be of high spectral and temporal purity and stability. This is commonly derived from AT cut quartz crystals to achieve the required purity. In addition, a temperature compensating circuit is frequently employed to achieve the required stability.

The low frequency clock is commonly used to operate a “real time clock” (RTC). This is commonly derived from a separate low frequency tuning fork-type crystal. This low frequency clock is used to operate the RTC during power-off or standby times. One of the disadvantages of using a tuning fork-type crystal is that the output frequency wanders from the ideal 32 kHz (stability problems) and that the output signal is not very pure. This type of output signal is adequate for many applications but some wireless applications are much more demanding. They require a spectrally pure high frequency source with high accuracy to operate the radio circuits. Applications such as GPS and CDMA operate the radio intermittently, and have to synchronise with external signal or data timing. These applications can benefit from greater accuracy of the RTC signal.

These applications commonly use X-cut turning fork type crystals to clock the RTC. These crystals have approximately 150 part-per-million (ppm) frequency variation over-40 to 85 degrees C. By contrast the AT cut crystal has less than 25 ppm frequency variation, and when used in conjunction with a temperature compensating circuit, may have less than 1 ppm frequency variation over 40 to 85 degrees C. This is known as a Temperature Compensated Crystal Oscillator (TCXO).

An oscillator with a conservation mode is disclosed in U.S. Pat. No. 6,163,228. In particular, this patent discloses an oscillator that is able to be switched between a normal and a low power mode. When in low power operating mode, the power is restricted to the crystal oscillator so that oscillation is maintained but there is no output. The time required to resume normal operation is almost instantaneous.

An oscillator using a low power crystal is disclosed in U.S. Pat. No. 5,155,453. This patent discloses a crystal oscillator that can operate in a normal and a low-power operating mode. When in low power operating mode, the power is restricted to the crystal oscillator so that oscillation is maintained but there is no output. The time required to resume normal operation is almost instantaneous.

A method and device for conserving power in a CDMA mobile telephone unit is discussed in PCT Patent Application No. WO 01/28108. This patent application discloses a method and system for switching between normal and low power (“sleep”) modes. When in normal operation, an accurate clock source is used, e.g. a voltage controlled temperature controlled crystal oscillator (VCTCXO). When in low power mode, a separate second low power low frequency crystal oscillator is used to generate 32 kHz; the power to the accurate clock source is limited.

### SUMMARY OF THE INVENTION

It is an object of the present invention to provide a crystal oscillator system which provides a low power low frequency clock in standby mode and which does not require more than one crystal.

Other objects of the invention are made apparent in the description of the preferred embodiments.

Accordingly, in a first aspect the present invention may be broadly the to consist in an integrated circuit system for providing at least a high frequency signal and a low frequency signal derived from an oscillator using a single high frequency crystal with circuitry the improvement comprising that have at least a higher power mode and a lower power mode;
a higher power output when the oscillator is in the higher power mode providing at least the high frequency signal and the low frequency signal. Also, it has a lower power output when the oscillator in the lower power mode providing at least the low frequency signal.

Preferably, the system further comprises a frequency divider receiving the high frequency signal as input and providing the low frequency signal as output.

Preferably, the single oscillator includes a bias generator reducing the bias current of the oscillator in the lower power mode.

Preferably, the single oscillator includes an amplitude control circuit reducing oscillator current in lower power mode.

Preferably, the two separate oscillator sections for the single high frequency crystal, a high power oscillator section, and a low power oscillator section, wherein the oscillator sections can be disabled by controlling the bias, or a switch, or are connected in parallel.

Preferably, the system further comprises a temperature sensor or voltage function of temperature generating circuit, and a compensation circuit having at least two modes corresponding to the higher power mode or the lower power mode and receives a voltage or temperature indication. Also, it compensates the high frequency signal for the frequency or temperature according to either the higher power mode or the lower power mode, where compensation in each mode is according to different sets of coefficients.

Preferably, the compensation circuit is enabled in the higher power mode disabled in the lower power mode.

Preferably, the temperature indication is provided as an external output in the lower power mode to allow external compensation.

Preferably, the compensation circuit is periodically enabled during the lower power mode providing a compensation voltage to the voltage sample and hold circuit which provides a compensation voltage to the oscillator. Also, two or more sets of coefficients are provided for the temperature compensating function generator above which may be selected so that compensation is optimum at the first and the second power modes.

Preferably, in lower power mode the bias current of the compensation circuit is reduced.

Preferably, the load capacitance switch reduces load capacitance of the oscillator in the lower power mode.

Preferably, the high frequency crystal operates in fundamental frequency in the lower power mode, and an odd order overtone frequency when in the higher power mode.

Preferably, the higher power mode is active on starting of the oscillator for at least a predetermined period.

Preferably, the frequency divider is a programmable divider configured to compensate for the effect of changes in temperature in the low frequency output frequency signal.

Preferably, the system further comprises at least one counter receiving the low frequency signal and generating an RTC output.

Preferably, the direct current power for the oscillator is connected in series with at least one of a buffer and/or divider circuit mode, and/or an AC gain stage of the oscillator, at least during the lower power mode.

Preferably, the high frequency crystal operates at a lower frequency in the lower power mode and providing an alternative lower power output from the divider to provide the low frequency signal.

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting.

### BRIEF DESCRIPTION OF THE DRAWINGS

FIG. 1 is a schematic of one preferred embodiment of the present invention;

FIG. 2 is a schematic of additional blocks and low power enable signal used in a preferred embodiment of a TCXO;

FIG. 3 is a schematic showing an improved second preferred embodiment of a TCXO employing sample and hold to reduce the power of the function generator;

FIG. 4 is a schematic showing one way that the power of an HF oscillator is reduced in low power mode;

FIG. 5 is a schematic showing an ALC (automatic level control) used to control oscillator power;

FIG. 6a is a schematic showing another embodiment of a low power oscillator, which is implemented by switching a single crystal resonator between a high power oscillator circuit, and a second low power oscillator circuit;

FIG. 6b is a schematic showing an alternate embodiment of FIG. 6a where only the outputs to the crystal are switched, and the high impedance inputs are left connected in common;

FIG. 7 is a schematic showing an oscillator with a tuning register, whose value is reset by the low power select line, to select minimum load capacitance, and thus reduce power consumption;

FIG. 8 is a schematic shows a TCXO oscillator whose load capacitance is reduced in low power mode, by switching to a fixed voltage;

FIG. 9 is a schematic showing one possible embodiment of an overtone switching oscillator; and

FIG. 10 is a schematic showing one possible embodiment of an arrangement of circuit blocks to reduce DC power consumption by putting the oscillator in series with the divider.

### DETAILED DESCRIPTION OF ILLUSTRATIVE EMBODIMENTS

The present invention relates to a timing system including an integrated circuit having an oscillator that provides both high and low frequency clock signals from a single high frequency crystal without the necessity of a tuning fork crystal. The low frequency signal is available for time-keeping applications, with low power consumption during “idle” periods. The high performance high frequency signal is available on demand for clock and frequency reference use. The oscillator of the present invention provides improved time-keeping accuracy, whilst size, cost and component count is reduced. Furthermore phase noise and other critical parameters of the high frequency oscillator are not compromised. Shock vulnerability, a known problem for tuning fork crystals, is reduced.

Current technology being discussed herein is microprocessor based, therefore references to “low clock signals” or “low frequency,” mean a real time clock (RTC) signal which is typically 32 kHz. Other frequencies near this frequency may also be used. A “high clock signal” or “high frequency” is one that is greater than 1 MHz, although typically this value will range between 10-40 megahertz (MHz).

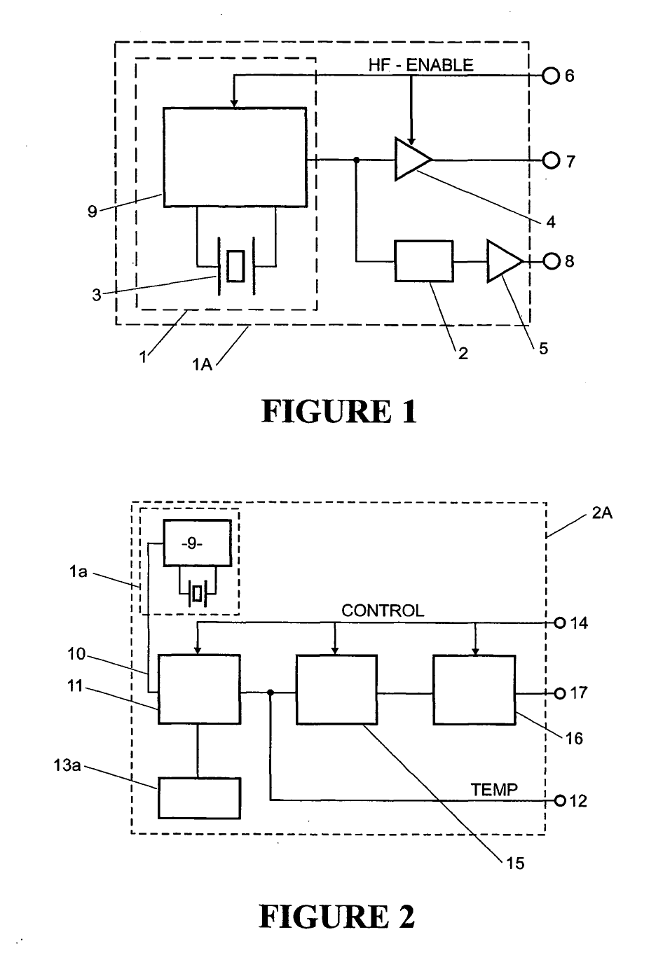

One preferred embodiment of the timing system of the present invention will be described with reference to FIG. 1. It consists of a high frequency crystal oscillator circuit 1 with an optional low-power mode, a low power frequency divider 2, and output buffers 4, 5. The oscillator circuit is comprised of an AT-cut crystal 3 and oscillator circuit 1 (including a temperature compensating circuit). The high frequency crystal oscillator circuit 1, low power frequency divider 2, and output buffers 4, 5 may be combined into a single integrated circuit (IC) 1a. The divider may be for example a binary divider, programmable divider, or a pulse swallowing divider. One skilled in the art will also appreciate that a number of other methods are possible to derive a low frequency RTC signal from the high frequency crystal oscillator output.

The preferred embodiment operates in two modes, high power (normal) mode and low-power mode or an idle state. In normal operation, both the high frequency (HF) output 7 and the low frequency (LF) output 8 are operational. The control line HF_ENABLE 6 enables the HF output buffers and driver circuits 4, and selects the high oscillator power. This provides best spectral purity in the HF output. This is important for wireless applications such as GPS and CDMA. The low frequency output 8 provides a RTC signal during the normal state. In idle state, the HF output 7 is disabled and the oscillator power is reduced while the LF output 8 remains available. Critical to very low power operation of the HF crystal oscillator 1 is a high crystal power mode to prevent drive level dependence (DLD) related starting problems.

The frequency divider 2, or at least the first few stages of the divider chain, is advantageously incorporated with the crystal oscillator IC. Incorporating it within the same IC allows the lowest power consumption to be achieved.

When the oscillator IC is reset, by power on or by microprocessor command, the oscillator 1a is automatically selected to be in the highest power oscillator mode. This reduces start-up time, and DLD related problems. This high power start-up mode may be ended automatically after a period timed by a counter attached to, or logic attached to, the frequency divider 2.

It is not essential to the operation of the oscillator that an exact frequency such as 32,768 kHz be produced at low frequency pin 8, as the associated microprocessor can easily make any required timing conversions. However where such a specific frequency is desired or required, an alternate embodiment may use a programmable divider instead of frequency divider 2. In yet a further implementation, counters may be provided whose values can be read by an external subsystem thus incorporating the RTC function into the oscillator.

Another embodiment of the timing system of the present invention will be described with reference to FIG. 2. In addition to the information disclosed above, a temperature compensating function generator 11 programmed by a set of stored coefficients, and frequency control input 10 are added to the oscillator 1a to form timing system 2a. This function generator typically contributes a large proportion of the power drain of the whole circuit.

In the simplest implementation of this embodiment, the function generator 11 will have its power turned off by a strobe line 14 in its idle state. This allows the oscillator 1a to be temperature compensated when in high power mode, and uncompensated when in idle mode.

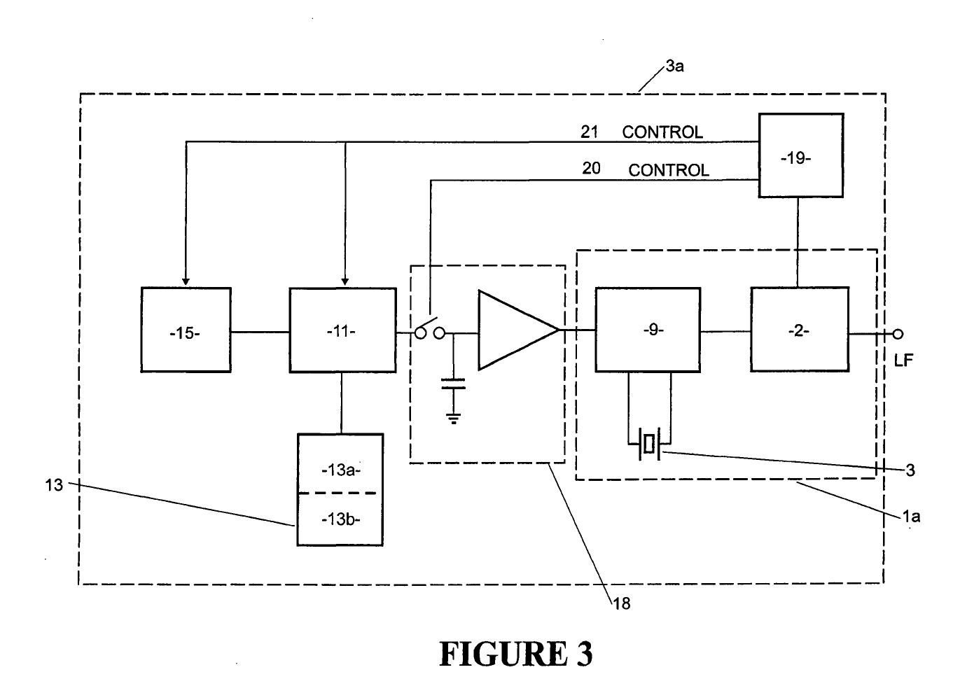

A more sophisticated implementation of this preferred embodiment is the timing circuit 3a shown in FIG. 3. During its idle state, function generator 11 will be briefly be turned on periodically and a sample and hold circuit 18 will be used to hold the compensating voltage during the intervening periods. The operating duty cycle of the function generator 11 will be low, to yield on average, a low power consumption. A method of doing this is to use a logic block 19 attached to the low power frequency divider 2. This results in a wavering frequency in the low frequency output 8. However short term frequency stability is less important in the low frequency signal, as RTC type users generally require cumulative timekeeping accuracy.

In yet another implementation, the bias currents of the temperature compensation subsystems (the function generator 11, temperature sensor 13, etc.) are reduced during low power modes. This will however alter the transfer function, and also increase the (short-term) noise to a level which would be unacceptable in the high-frequency output.

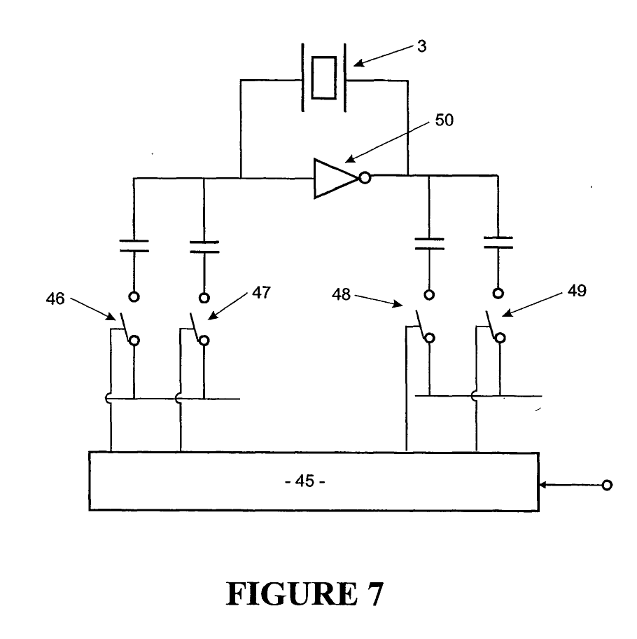

A distinct limitation of changing the power drain of critical circuit elements such as the oscillator (3a) and function generator, is that the centre frequency, and the frequency-temperature characteristic, is different between the high power and low power modes. This can be addressed in a number of ways. As shown in FIG. 3, one such method is to add a second (or more) bank of coefficient registers 13b to the function generator 11 and select or reload these to the function generator 11 when a different power mode is selected. The first bank 13a contains coefficients derived and optimised for the high power mode, whilst the second bank 13b contains coefficients derived and optimised for the low power mode, thus ensuring optimum performance under both conditions. As shown in FIG. 7, the oscillator has tuning registers 45 which are used to bring the oscillator frequency on to its nominal value, and a second or further banks of tuning values may also be added so that the frequency is optimal during low power modes.

A second method is to leave the oscillator 3a uncompensated during its idle state, and provide a table of coefficients 13 that may be used to calculate frequency in an external subsystem such as a microprocessor. This table of coefficients 13 can be stored within the oscillator packaging, or supplied externally, such as on a disc or via a network, and linked to a unique identifier that allows software to find the set of coefficients that is to be used with a particular oscillator IC. Such a unique identifier can be stored within the oscillator 3a and read electrically, or applied to the external surface and read by other means, for example as a data matrix which is read optically.

A temperature sensor 15 output can optionally be provided from the oscillator 3a. This can be used for the external calculation of the frequency correction as described above. The temperature sensor 15 and voltage reference 16 are able to be powered down by strobe line 21.

In yet another embodiment of the timing system 3a of the present invention, an additional low power mode is provided. The HF oscillator 1a can operate at reduced power and a reduced frequency. A different output may be taken from some intermediate point on the divider chain 2 since the input is now a lower frequency, to obtain the LF output. This mode provides a clock signal for microprocessors with reduced 1/2 CV² power loss (as less of the divider chain is used) and reduced power drain in the consuming integrated circuits e.g. GPS IC, or microprocessor.

The HF oscillator with low power modes 1A can be implemented in a variety of ways. Three of these will now be described.

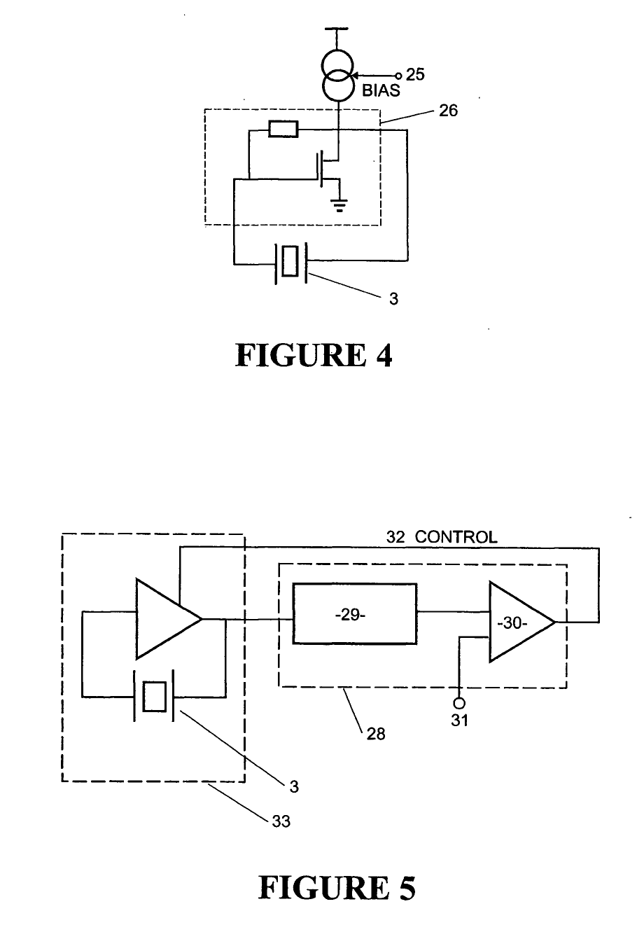

In the simple oscillator circuit 26 using a single high frequency crystal 3 shown in FIG. 4 the current consumption of the oscillator circuit can be adjusted by its bias generator via a control line 25. Commonly, this might be done through a current mirror. This also adjusts the crystal current and power. Other forms of adjustment are also possible, for example adjusting the gate bias voltage of the FETFET.

Amplitude control circuitry 28 is used in the embodiment shown in FIG. 5. The amplitude control circuitry 28 consists of a detection circuit 29 and reference level circuit 30. The amplitude control circuit 28 adjusts the amplitude of the output of oscillator 33 by adjusting the oscillator power control line 32. An amplitude control signal 31 sets the amplitude of oscillation, and the current is indirectly set by the level control circuit by adjusting the oscillator, for example by adjusting bias current as above. In such an arrangement the power supply to the amplitude control circuit 28 can advantageously be strobed and a sample and hold arrangement used to hold the control output, as discussed in relation to the TCXO function generator of FIG. 2, to reduce the average current consumption. This is possible because the high Q of the crystal oscillator means that the level of the oscillation changes very slowly, allowing the duty cycle to be low, and the strobe rate to be far lower than the crystal operating frequency.

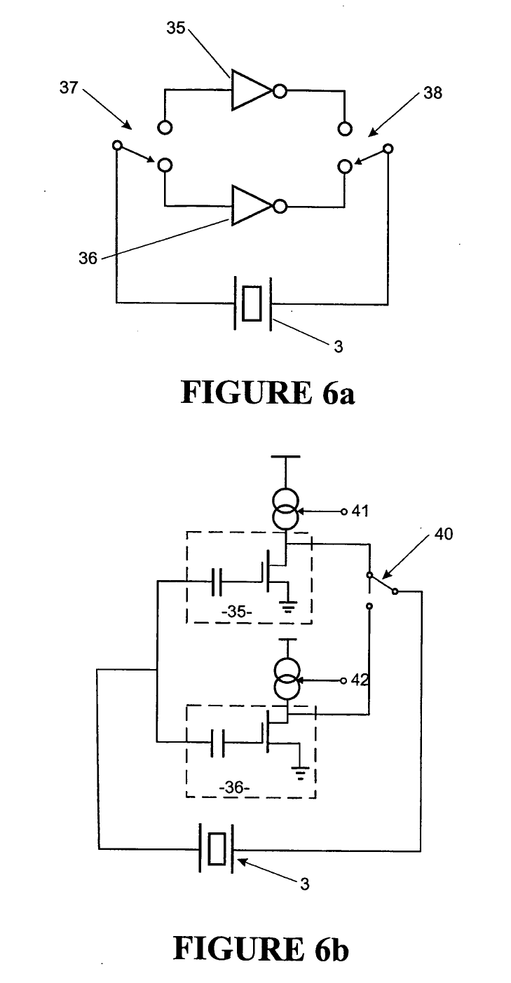

In a third implementation two distinct oscillators are used as shown in FIGS. 6a and 6b. They are connected directly or by switches 37, 38, 40 to a single high frequency crystal 3, where one oscillator is a high power oscillator 35, and the other is a low power oscillator 36. In FIG. 6a, both connections on crystal 3 are able to be switched 37, 38, while in FIG. 6b only one of the crystals connections is able to be switched by a switch 40.

In the implementation shown in FIG. 6b, both oscillators 35, 36, using field effect transistors as active elements, may have bias adjust inputs 41, 42. As the FET inputs have high impedances, it is not necessary to switch the inputs, and only the outputs are switched by the single switch 40. The oscillator in use is selected by the bias controls 41, 42, or by other means such as controlling the gate bias. It is also possible that only the high power oscillator 35, has a bias adjustment input. Due to the much higher bias current when the high power mode is enabled, it may be unnecessary to turn off the low power oscillator 36. In some circuit arrangements the switch 40 is also unnecessary, and the oscillators can simply be connected in parallel and bias control used to select which is operational. In FIG. 6b both oscillators are depicted as simple single transistor oscillators. More complicated oscillator circuits with multiple gain stages are also possible, and for the low power oscillator may be preferable as a multiple transistor gain stage can have lower power consumption for the same gain.

The power consumption of the HF crystal oscillator is also dependent on the load capacitance of the crystal. At high load capacitance current consumption of the oscillator is greater, but performance may be better in certain respects. In certain circuits, particularly TSXO type circuits, it is advantageous to reduce the load capacitance of the crystal oscillator when operating in low power modes. This might be achieved by switches 46-49 as shown in FIG. 7, changing register values in a register 45 that controls load capacitance or tuning.

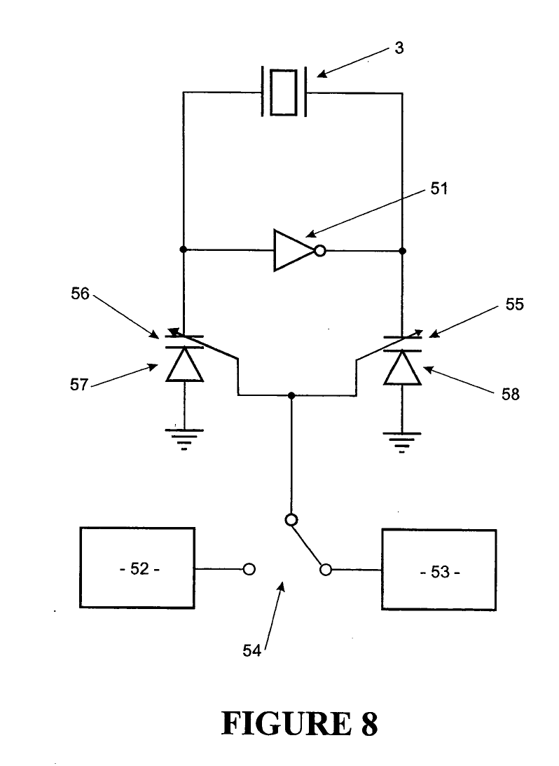

Alternatively, this can be done by forcing a certain voltage onto a voltage controlled impedance such that is operates at the lowest power, dissipation point as shown in FIG. 8. Here, the control voltage of voltage variable capacitance elements 55-58, is switched by a switch 54 between a function generator 52, and an optimum voltage 53 for low power operation.

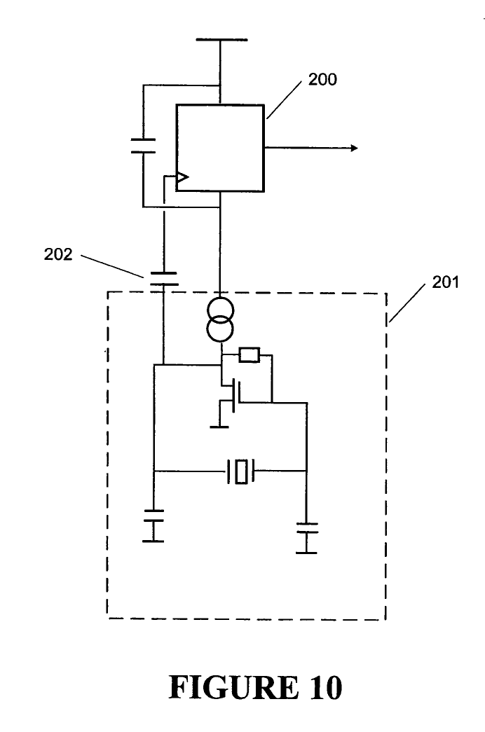

In another implementation of the timing system, an oscillator circuit is arranged so that its power supply is effectively in series with other subsystems of the oscillator. FIG. 10 shows an arrangement where the oscillator 201 is in series with the divider 200, and the oscillator signal is coupled to the divider by capacitor 202.

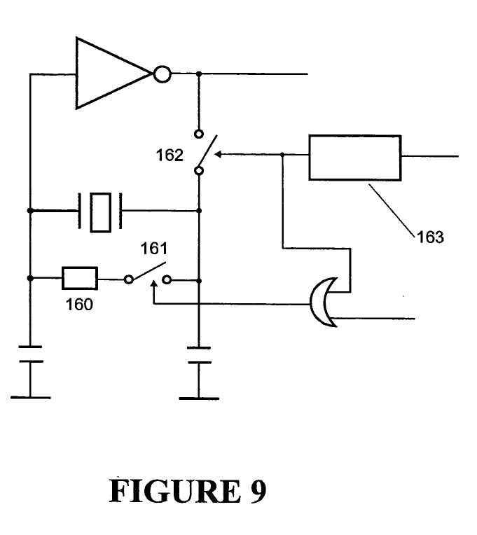

This is advantageous as the total power consumption of the timing system IC is reduced, whilst keeping the oscillator current as high as possible. This is viable because the oscillation amplitude is very low when in low power modes and the oscillator can easily operate at low supply voltages. Other subsystems that might be put in series with the oscillator include the oscillator buffers and frequency dividers. Other subsystems may also exist for this purpose. Putting the divider in series with the oscillator can also be advantageous as the voltage available to the oscillator can be greatest when starting as the divider does not require any current until operational.

Where an overtone crystal is used, it may be advantageous to operate the oscillator on an overtone such as the 3^{rd} or 5^{th}, whilst in high power modes, and at the fundamental frequency when in low power modes. Lower power consumption of the oscillator and the dividers is possible at the fundamental. This arrangement is particularly advantageous for TSXO type circuits, which employ low pullabilty overtone oscillators. Such an arrangement might be achieved by switching one of the known fundamental suppression circuits. FIG. 9 shows an example where the overtone suppression resistor 160 is switched into circuit by switch 161 when in high power mode, and out of circuit when in low power mode. One problem that arises is the reluctance of a crystal oscillator to change to another mode or overtone, when operating in another. In this case the oscillator may be stopped before the transition occurs. An RC (resistor-capacitor) timed monostable 163 is used to momentarily disconnect the oscillator active element from the crystal via switch 162, and increase the loss of the resonant circuit by switching in resistor 160 through switch 161. The monostable pulse is long enough to stop the oscillation. In other implementations the oscillator might be turned off to stop oscillation, or the bias current might be reduced to a level such that only fundamental oscillation is possible. It may be advantageous that different means are used to effect a change from fundamental to overtone, than are used to change from overtone to fundamental. Where a temperature sensing oscillator is required, a dual mode oscillator configuration can be advantageously used. In such an operation the crystal can simultaneously operate on both the fundamental and the 3^{rd} overtone resonances. Such oscillators are known in the art. In this case, the in high power mode both the overtone and fundamental oscillators are active, while in the low power mode only the fundamental oscillator is active.

1. In an integrated circuit system for providing at least a high frequency signal and a low frequency signal derived from an oscillator using a single high frequency crystal with circuitry, the improvement comprising:
said oscillator having at least a higher power mode and a lower power mode;
a higher power output when said oscillator in said higher power mode providing at least said high frequency signal and said low frequency signal; and
a lower power output when said oscillator in said lower power mode providing at least said low frequency signal.

2. In a system as claimed in claim 1, the improvement further comprising a frequency divider receiving said high frequency signal as input and providing said low frequency signal as output.

3. In a system as claimed in claim 1, the improvement further comprising a single oscillator including a bias generator reducing the bias current of said oscillator in said lower power mode.

4. In a system as claimed in claim 1, the improvement further comprising a single oscillator including an amplitude control circuit reducing oscillator current in lower power mode.

5. In a system as claimed in claim 1, the improvement further comprising two separate oscillator sections for said single high frequency crystal, a high power oscillator section, and a low power oscillator section, wherein the oscillator sections can be disabled by controlling the bias, or a switch, or are connected in parallel.

6. In a system as claimed in claim 1, the improvement further comprising:
a temperature sensor or voltage function of temperature generating circuit; and
a compensation circuit having at least two modes corresponding to said higher power mode or said lower power mode and receiving a voltage or temperature indication, and compensating said high frequency signal for the frequency or temperature according to either said higher power mode or said lower power mode, wherein compensation in each mode is according different sets of coefficients.

7. In a system as claimed in claim 6, the improvement further comprising said compensation circuit being enabled in said higher power mode disabled in said lower power mode.

8. In a system as claimed in claim 7, the improvement further comprising said temperature indication provided as an external output in said lower power mode to allow external compensation.

9. In a system as claimed in claim 6, the improvement further comprising:
a voltage sample and hold circuit wherein said compensation circuit is periodically enabled during said lower power mode providing a compensation voltage to voltage sample and hold circuit which provides a compensation voltage to said oscillator, wherein two or more sets of coefficients are provided for the temperature compensating function generator above which may be selected so that compensation is optimum at said first and said second power modes.

10. In a system as claimed in claim 1, the improvement further comprising reducing the bias current of said compensation circuit in said lower power mode.

11. In a system as claimed in claim 1, the improvement further comprising a load capacitance switch reducing load capacitance of said oscillator in said lower power mode

12. In a system as claimed in claim 1, the improvement further comprising said high frequency crystal operates in fundamental frequency in said lower power mode, and an odd order overtone frequency when in said higher power mode.

13. In a system as claimed in claim 1, the improvement further comprising said higher power mode is active on starting of said oscillator for at least a predetermined period.

14. In a system as claimed in claim 2, the improvement further comprising said frequency divider is a programmable divider configured to compensate for the effect of changes in temperature in said low frequency output frequency signal.

15. In a system as claimed in claim 1, the improvement further comprising at least one counter receiving said low frequency signal and generating an RTC output.

16. In a system as claimed in claim 1, the improvement further comprising a direct current power for said oscillator is connected in series with at least one of a buffer and/or divider circuit mode, and/or an AC gain stage of said oscillator, at least during said lower power mode.

17. In a system as claimed in claim 1, the improvement further comprising said high frequency crystal operates at a lower frequency in said lower power mode and providing an alternative lower power output from said divider to provide said low frequency signal.
